(19) United States
(12) Patent Application Publication
(10) Pub. No.: US 2023/0245965 A1
(43) Pub. Date: Aug. 3, 2023

(54) SURFACE FINISH STRUCTURE OF MULTI-LAYER SUBSTRATE

(71) Applicant: PRINCO CORP., Hsinchu City (TW)

(72) Inventor: Pei-Liang CHIU, Hsinchu City (TW)

(21) Appl. No.: 18/096,039

(22) Filed: Jan. 12, 2023

(30) Foreign Application Priority Data
Jan. 28, 2022 (TW) 111104172

(51) Int. Cl. H01L 23/498; H01L 21/48

(52) U.S. Cl. CPC H01L 23/49838; H01L 21/4846; H01L 24/05

(57) ABSTRACT

A surface finish structure of a multi-layer substrate includes: a dielectric layer; at least one pad layer formed in the dielectric layer; and at least one protective metal layer formed on the at least one pad layer and bonded to the at least one pad layer, wherein the at least one protective metal layer only covers an upper surface of the at least one pad layer, the at least one protective metal layer is configured to be soldered to or contact an external element, and there is no height difference between an upper surface of the at least one protective metal layer and an upper surface of the dielectric layer.

### FIELD OF DISCLOSURE

The present disclosure relates to the technical field of multi-layer substrates, and more particularly to a surface finish structure of a multi-layer substrate.

### BACKGROUND

Please refer to FIG. 1. FIG. 1 illustrates a conventional surface finish structure of a multi-layer substrate.

The surface finish structure of the multi-layer substrate includes a dielectric layer 100, an electrically conductive seed layer 102, a pad layer 104, a protective metal layer 106, and a solder mask layer 108.

When the surface finish structure of the multi-layer substrate is manufactured, a groove 110 is formed on the dielectric layer 100 by a photoresist layer (not shown). Then, the electrically conductive seed layer 102 is formed on a bottom of the groove 110 by a sputtering method or an evaporation method and is bonded to the dielectric layer 100. The electrically conductive seed layer 102 is served as a seed of the pad layer 104. Then, the photoresist layer (not shown) is removed. The pad layer 104 grows up upwardly and laterally based on the center of the electrically conductive seed layer 102 by an electroplating method or an electroless plating method. The protective metal layer 106 is formed, by an electroplating method or an electroless plating method, on the pad layer 104 to cover the pad layer 104 totally. Finally, the solder mask layer 108 is formed to expose the protective metal layer 106 partially or totally.

When an external element requires to be soldered on the pad layer 104 made of copper material, tin material or a solder flux is used for adhering the external element to the pad layer 104. An objective of the protective metal layer 106 is to avoid a situation that the tin material or the solder flux and the copper of the pad layer 104 are melted mutually to form an intermetallic compound (IMC) when the tin material or the solder flux contacts the copper of the pad layer 104. In this situation, the surface finish structure of the multi-layer substrate is fragile, and product reliability is lowered.

Please refer to FIG. 2. FIG. 2 illustrates another conventional surface finish structure of a multi-layer substrate.

A difference between the surface finish structure of the multi-layer substrate in FIG. 2 and the surface finish structure of the multi-layer substrate in FIG. 1 is that the photoresist layer (not shown) is not removed in FIG. 2 after the electrically conductive seed layer 102 is formed. The photoresist layer (not shown) is removed after the pad layer 104 is formed by an electroplating method or an electroless plating method.

In the surface finish structures of the multi-layer substrates in FIG. 1 and FIG. 2, the solder mask layer 108 can be formed first. The groove 110 is formed in the solder mask layer 108. The electrically conductive seed layer 102, the pad layer 104, and the protective metal layer 106 are formed in the groove 110. Alternatively, the pad layer 104 and the protective metal layer 106 can be formed first, and then the solder mask layer 108 is formed. The groove 110 is formed to expose the protective metal layer 106.

However, when the pad layer 104 and the protective metal layer 106 are formed by the electroplating method or the electroless plating method, the pad layer 104 and the protective metal layer 106 expand from lateral sides of the electrically conductive seed layer 102. Accordingly, the pad layer 104 and the protective metal layer 106 are widened. As shown in FIG. 1, generally speaking, when a thickness of the pad layer 104 is 10 micrometers (μm), a width of one side of the pad layer 104 which externally expands from one side of the electrically conductive seed layer 102 is ranged from 2 μm to 4 μm. That is, a width of the whole (two sides) of the pad layer 104 which externally expands from two sides of the electrically conductive seed layer 102 is ranged from 4 μm to 8 μm. A width of the whole (two sides) of the protective metal layer 106 which externally expands from the two sides of the electrically conductive seed layer 102 is ranged from 6 μm to 10 μm.

In the surface finish structure of the multi-layer substrate in FIG. 2, a width of the whole (two sides) of the protective metal layer 106 which externally expands from the two sides of the electrically conductive seed layer 102 is also ranged from 6 μm to 10 μm.

Furthermore, the processes of forming the pad layer 104 and the protective metal layer 106 by the electroplating method or the electroless plating method are made in solutions. Many factors, for example, concentration, temperature, material and so on, affect the ranges of the pad layer 104 and the protective metal layer 106 which externally expand from the electrically conductive seed layer 102. As such, it is difficult to control the sizes of the pad layer 104 and the protective metal layer 106.

Furthermore, due to miniaturization of line pitches in integrated circuits, a horizontal pad pitch between two adjacent pad layers is getting smaller and smaller to meet the fast speed of miniaturization of integrated circuits of wafers. The horizontal pad pitch with the speed of miniaturization was approximately equal to 10 nanometers (nm) four years ago, and it is 5 nm nowadays. In year 2026, the horizontal pad pitch with the speed of miniaturization will be expected to advance to 2 nm even 1 nm. To meet miniaturization of wafers, a distance between two adjacent electrical connection points of a bare die will be expected to be smaller than 30 μm five years later from 80 μm to 100 μm nowadays. When a pad pitch between two adjacent pad layers (configured to be electrically connected to electrical connection points of a bare die) is smaller than 30 μm, a width of each pad layer is smaller than 18 μm. Unexpected expansion in the electroplating method and the electroless plating method will become a barrier of fining the pad layer 104 and the protective metal layer 106 in FIG. 1 and FIG. 2.

Furthermore, in the prior art, a pad layer and a protective metal layer are generally and partially higher or lower than an upper surface of a dielectric layer, so that there is a clear height difference between the dielectric layer and the protective metal layer. When an exposed metal surface of a chip is connected to this multi-layer substrate by flip-chip bonding, air bubbles are generated to damage the package adhesion of the chip.

Therefore, there is a need to solve the above-mentioned problems in the prior art.

### SUMMARY OF DISCLOSURE

The present disclosure provides a surface finish structure of a multi-layer substrate capable of solving the problems in the prior art.

The surface finish structure of a multi-layer substrate includes: a dielectric layer; at least one pad layer formed in the dielectric layer; and at least one protective metal layer formed on the at least one pad layer and bonded to the at least one pad layer, wherein the at least one protective metal layer only covers an upper surface of the at least one pad layer, the at least one protective metal layer is configured to be soldered to or contact an external element, and there is no height difference between an upper surface of the at least one protective metal layer and an upper surface of the dielectric layer.

The surface finish structure of a multi-layer substrate includes: a dielectric layer; at least one pad layer, wherein a part of the at least one pad layer is formed in the dielectric layer; and at least one protective metal layer formed on the at least one pad layer and bonded to the at least one pad layer, wherein the at least one protective metal layer only covers an upper surface of the at least one pad layer, the at least one protective metal layer is configured to be soldered to or contact an external element, and there is no height difference between an upper surface of the at least one protective metal layer adjacent to the dielectric layer and an upper surface of the dielectric layer.

In the surface finish structure of the multi-layer substrate of the present disclosure, the protective metal layer mainly only covers the upper surface of the pad layer and does not externally expand from two sides of the pad layer. Accordingly, the problem that the pad layer and the protective metal layer cannot be fined due to unexpected expansion in the prior art can be solved. Furthermore, since there is no height difference between the upper surface of the protective metal layer (or the upper surface of the protective metal layer adjacent to the dielectric layer) and the upper surface of the dielectric layer, air bubbles are not generated between the dielectric layer and the protective metal layer when a surface of a chip is connected to the surface finish structure of the multi-layer substrate by flip-chip bonding. Accordingly, package adhesion of the chip is not weakened, and the problem of poor electrical contact between a surface of the multi-layer substrate and the external component can be avoided to achieve corresponding technical effect. Furthermore, in the surface finish structure of the multi-layer substrate of the present disclosure, there is no height difference between the upper surface of the protective metal layer (or the upper surface of the protective metal layer adjacent to the dielectric layer) and the upper surface of the dielectric layer. When the surface finish structure of the multi-layer substrate is connected to the metal exposed surface of the chip by flip-chip bonding, the air bubbles are not generated between the dielectric layer and the protective metal layer even if the surface finish structure of the multi-layer substrate is completely bonded to the exposed metal surface of the chip without gaps. This is crucial technical effect in high-end semiconductor packaging. When air bubbles are generated after the surface finish structure of the multi-layer substrate is completely bonded to the exposed metal surface of the chip, the air bubbles expand with heat emitted by the chip during operation. At least one electrical connection point of the chip and at least one pad of the multi-layer substrate which are bonded by flip-chip bonding are disconnected from a contacting state. That is, the chip and the multi-layer substrate are changed from a short circuit to an open circuit.

### BRIEF DESCRIPTION OF DRAWINGS

FIG. 1 illustrates a conventional surface finish structure of a multi-layer substrate.

FIG. 2 illustrates another conventional surface finish structure of a multi-layer substrate.

FIG. 3 illustrates a surface finish structure of a multi-layer substrate in accordance with an embodiment of the present disclosure.

FIG. 4A to FIG. 4C illustrate a flow chart of a method for manufacturing a surface finish structure of a multi-layer substrate in accordance with an embodiment of the present disclosure.

FIG. 5 illustrates that a surface finish structure of a multi-layer substrate in accordance with another embodiment of the present disclosure.

FIG. 6 illustrates that a chip is connected to the surface finish structure of the multi-layer substrate in FIG. 5 by flip-chip bonding.

FIG. 7A to FIG. 7C illustrate a flow chart of a method for manufacturing a surface finish structure of a multi-layer substrate in accordance with another embodiment of the present disclosure.

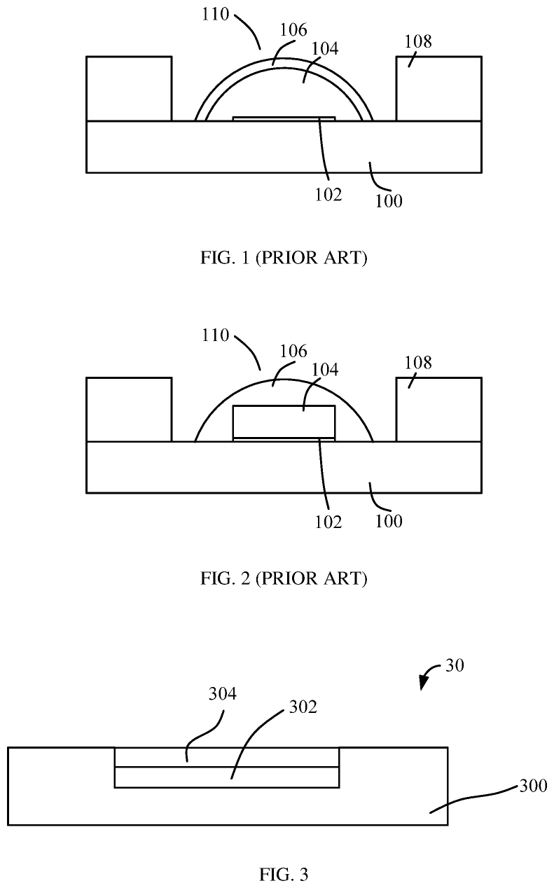

### DETAILED DESCRIPTION

To make the objectives, technical schemes, and technical effects of the present disclosure clearer and more definitely, the present disclosure will be described in detail below by using embodiments in conjunction with the appending drawings. It should be understood that the specific embodiments described herein are merely for explaining the present disclosure, and as used herein, the term “embodiment” refers to an instance, an example, or an illustration but is not intended to limit the present disclosure. In addition, the articles “a” and “an” as used in the specification and the appended claims should generally be construed to mean “one or more” unless specified otherwise or clear from the context to be directed to a singular form. Also, in the appending drawings, the components having similar or the same structure or function are indicated by the same reference number.

Please refer to FIG. 3. FIG. 3 illustrates a surface finish structure 30 of a multi-layer substrate in accordance with an embodiment of the present disclosure.

The surface finish structure 30 of the multi-layer substrate includes a dielectric layer 300, at least one pad layer (one pad layer 302 is included in the present embodiment), and at least one protective metal layer (one protective metal layer 304 is included in the present embodiment).

A material of the dielectric layer 300 is polyimide (PI).

The pad layer 302 is formed in the dielectric layer 300. In detail, the pad layer 302 is totally embedded in the dielectric layer 300. A material of the pad layer 302 is copper.

The protective metal layer 304 is formed on the pad layer 302 and bonded to the pad layer 302. The protective metal layer 304 mainly only covers an upper surface of the pad layer 302. The protective metal layer 304 is configured to be soldered to or contact an external element. In detail, the protective metal layer 304 does not externally expand from two sides of the pad layer 302 and does not affect original functions of the pad layer 302 and the protective metal layer 304. There is no height difference between an upper surface of the protective metal layer 304 and an upper surface of the dielectric layer 300.

Since there is no height difference between the upper surface of the protective metal layer 304 and the upper surface of the dielectric layer 300, air bubbles are not generated between the dielectric layer 300 and the protective metal layer 304 when a surface of a chip is connected to the surface finish structure 30 of the multi-layer substrate by flip-chip bonding. Accordingly, package adhesion of the chip is not weakened, and the problem of poor electrical contact between a surface of the multi-layer substrate and the external component can be avoided. This is another technical effect in the present disclosure.

A material of the protective metal layer 304 is selected from the group consisting of chromium, nickel, palladium, and gold.

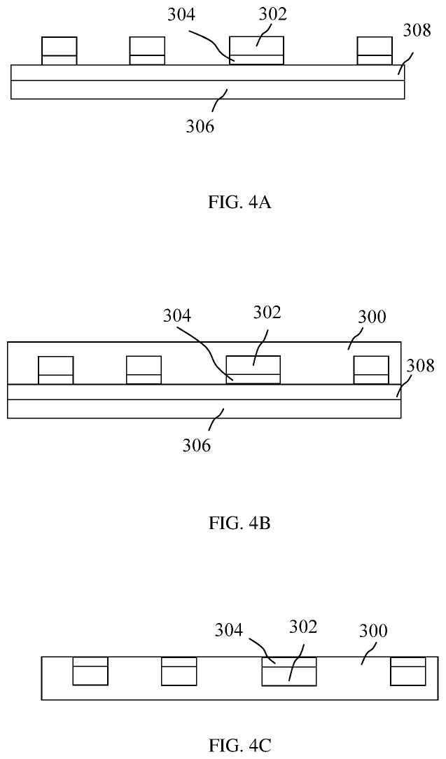

Please refer to FIG. 4A to FIG. 4C. FIG. 4A to FIG. 4C illustrate a flow chart of a method for manufacturing a surface finish structure of a multi-layer substrate in accordance with an embodiment of the present disclosure.

First, in FIG. 4A, a solder mask layer 308 is formed on a surface of a flat supporting plate 306. At least one protective metal layer 304 (multiple protective metal layers 304 are included in the present embodiment) is formed on the solder mask layer 308. Then, at least one pad layer 302 (multiple pad layers 302 are included in the present embodiment) is formed on the at least one protective metal layer 304.

In an embodiment, a silicon wafer with good surface flatness can be used as the supporting plate 306. The solder mask layer 308 can be formed on the supporting plate 306 by a coating method. Then, the at least one protective layer 304 and the at least one pad layer 302 are sequentially formed on a surface of the solder mask layer 308 by an etching method, an electroplating method, or a lithography method.

In FIG. 4B, a dielectric layer 300 is formed on the solder mask layer 308 and the at least one pad layer 302, and the dielectric layer 300 covers the at least one solder pad layer 302, the at least one protective metal layer 304, and the solder mask layer 308. Specifically, the at least one protective metal layer 304 and the at least one pad layer 302 are completely embedded in the dielectric layer 300 (as shown in FIG. 4C). After the dielectric layer 300 is formed, at least one subsequent manufacturing process can be performed to complete the whole of the multi-layer substrate according to multi-layer board design.

In FIG. 4C, the solder mask layer 308 is separated from the dielectric layer 300, and the dielectric layer 300 and the at least one protective metal layer 304 and the at least one pad layer 302 which are embedded in the dielectric layer 300 are flipped to obtain the multi-layer substrate where there is no height difference between an upper surface of the at least one protective metal layer 304 and an upper surface of the dielectric layer 300.

In an embodiment, the method for separating the multi-layer substrate (including the dielectric layer 300, the at least one pad layer 302, and the at least one metal protection layer 304) from a surface of the solder mask layer 308 can be a sacrificial layer method, a method for weakening a surface of a supporting plate, or the like.

The at least one protective metal layer 304 is bonded to the at least one pad layer 302. The at least one protective metal layer 304 mainly only covers an upper surface of the at least one pad layer 302. The at least one protective metal layer 304 is configured to be soldered to or contact an external element.

In the surface finish structure of the multi-layer substrate of the present disclosure, the protective metal layer mainly only covers the upper surface of the pad layer and does not externally expand from two sides of the pad layer. Accordingly, the problem that the pad layer and the protective metal layer cannot be fined due to unexpected expansion in the prior art can be solved. Furthermore, since there is no height difference between the upper surface of the protective metal layer and the upper surface of the dielectric layer, air bubbles are not generated between the dielectric layer and the protective metal layer when a surface of a chip is connected to the surface finish structure of the multi-layer substrate by flip-chip bonding. Accordingly, package adhesion of the chip is not weakened, and the problem of poor electrical contact between a surface of the multi-layer substrate and the external component can be avoided. This is another technical effect in the present disclosure.

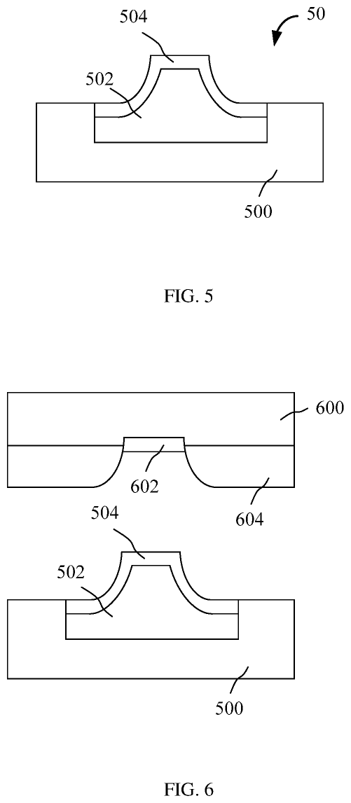

Please refer to FIG. 5. FIG. 5 illustrates a surface finish structure 50 of a multi-layer substrate in accordance with another embodiment of the present disclosure.

The surface finish structure 50 of the multi-layer substrate includes a dielectric layer 500, at least one pad layer 502, and at least one protective metal layer 504.

A material of the dielectric layer 500 is polyimide (PI).

A part of the at least one pad layer 502 is formed in the dielectric layer 500. In detail, two sides (i.e., a periphery) of the at least one pad layer 502 are (is) totally embedded in the dielectric layer 500. A middle part of the at least one pad layer 502 is a protrusion shape. In detail, the middle part of the at least one pad layer 502 is higher than the two sides (i.e., the periphery) of the at least one pad layer 502 close to the dielectric layer 500. A material of the pad layer 502 is copper.

The at least one protective metal layer 504 is formed on the at least one pad layer 502 and bonded to the at least one pad layer 502. The at least one protective metal layer 504 mainly only covers an upper surface of the at least one pad layer 502. The at least one protective metal layer 504 is configured to be soldered to or contact an external element. In detail, the at least one protective metal layer 504 does not externally expand from two sides of the at least one pad layer 502 and does not affect original functions of the at least one pad layer 502 and the at least one protective metal layer 504. There is no height difference between an upper surface of the at least one protective metal layer 504 adjacent to the dielectric layer 500 and an upper surface of the dielectric layer 500. A material of the at least one protective metal layer 304 is selected from the group consisting of chromium, nickel, palladium, and gold.

It can be appreciated from FIG. 5 that a part of the at least one protective metal layer 504 is formed in the dielectric layer 500. In detail, two sides (i.e., a periphery) of the at least one pad layer 502 are (is) totally embedded in the dielectric layer 500. A middle part of the at least one pad layer 502 is a protrusion shape. In detail, the middle part of the at least one pad layer 502 is higher than the two sides (i.e., the periphery) of the at least one pad layer 502 close to the dielectric layer 500. Since a surface of a chip is not necessarily flat, the middle part of the at least one protective metal layer 504 is the protrusion shape in order to match the appearance of the chip and to closely adhere to the surface of the chip.

Since there is no height difference between the upper surface of the at least one protective metal layer 504 adjacent to the dielectric layer 500 and the upper surface of the dielectric layer 500, air bubbles are not generated between the dielectric layer 500 and the at least one protective metal layer 504 when a surface of a chip is connected to the surface finish structure 50 of the multi-layer substrate by flip-chip bonding. Accordingly, package adhesion of the chip is not weakened, and the problem of poor electrical contact between a surface of the multi-layer substrate and the external component can be avoided. This is another technical effect in the present disclosure.

Shapes of the at least one pad layer 502 and the at least one protective metal layer 504 in FIG. 5 are designed according to the surface shape of the chip to be connected by flip-chip bonding. The exposed metal surface of the chip and the shape of the periphery thereof determine the surface shape of the chip to achieve a complete connecting state by flip-chip bonding.

With reference to a shape of an exposed metal surface 602 of a chip 600 and a shape of an insulating layer 604 around the exposed metal surface 602, the shapes of at least one pad layer 502 and the at least one protective metal layer 504 of the surface finish structure 50 of the multi-layer substrate are designed according to the shapes of the exposed metal surface 602 of the chip 600 and the shape of the insulating layer 604 around the exposed metal surface 602 to achieve the objective of the complete connecting state by flip-chip bonding.

Furthermore, it should be described that in the embodiment shown in FIG. 6, the exposed metal surface 602 of the chip 600 is recessed in the insulating layer 604, and the surface finish structure 50 of the multi-layer substrate is a protrusion shape corresponding to the recessed shape to achieve the complete connecting state by flip-chip bonding. In another embodiment, when the exposed metal surface of the chip protrudes from the insulating layer, the surface finish structure 50 of the multi-layer substrate is a recessed shape corresponding to the protrusion shape.

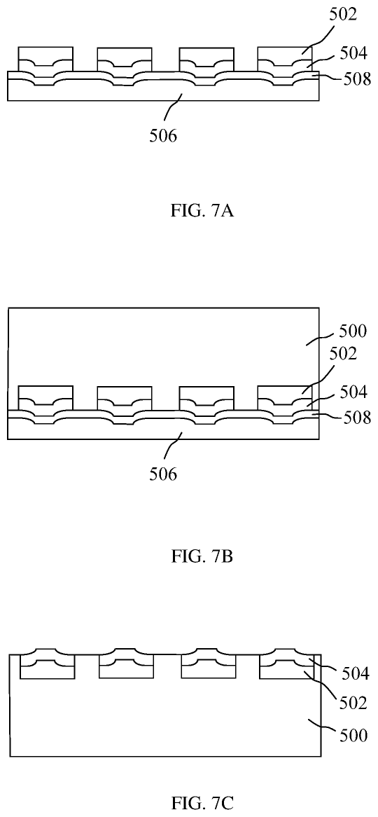

Please refer to FIG. 7A to FIG. 7C. FIG. 7A to FIG. 7C illustrate a flow chart of a method for manufacturing a surface finish structure of a multi-layer substrate in accordance with another embodiment of the present disclosure.

First, in FIG. 7A, a solder mask layer 508 is formed on a surface of a supporting plate 506. At least one protective metal layer 504 (multiple protective metal layers 504 are included in the present embodiment) is formed on the solder mask layer 508. Then, at least one pad layer 502 (multiple pad layers 502 are included in the present embodiment) is formed on the at least one protective metal layer 504.

In another embodiment, a preformed glass, metal or ceramic plate can be used as the supporting plate 506, and the solder mask 508 is formed on the supporting plate 506 by a coating method. Then, the at least one protective layer 504 and the at least one pad layer 502 are sequentially formed on a surface of the solder mask layer 508 by an etching method, an electroplating method, or a lithography method.

In FIG. 7B, a dielectric layer 500 is formed on the solder mask layer 508 and the at least one pad layer 502, and the dielectric layer 300 covers the at least one solder pad layer 502, the at least one protective metal layer 504, and the solder mask layer 508. Specifically, a part (i.e., two sides) of the at least one protective metal layer 504 and two sides of the at least one pad layer 502 are totally embedded in the dielectric layer 500 (as shown in FIG. 7C). After the dielectric layer 500 is formed, at least one subsequent manufacturing process can be performed to complete the whole of the multi-layer substrate according to multi-layer board design.

In FIG. 7C, the solder mask layer 508 is separated from the dielectric layer 500, and the dielectric layer 500, the at least one protective metal layer 504, and the at least one pad layer 502 (the two sides of the at least one protective metal layer 504 and the two sides of the at least one pad layer 502 are embedded in the dielectric layer 500) are flipped to obtain the multi-layer substrate where there is no height difference between an upper surface of the at least one protective metal layer 504 adjacent to the dielectric layer 500 and an upper surface of the dielectric layer 500.

In another embodiment, the method for separating the multi-layer substrate (including the dielectric layer 500, the at least one pad layer 502, and the at least one metal protection layer 504) from a surface of the solder mask layer 508 can be a sacrificial layer method, a method for weakening a surface of a supporting plate, or the like.

The at least one protective metal layer 504 is bonded to the at least one pad layer 502. The at least one protective metal layer 504 mainly only covers an upper surface of the at least one pad layer 502. The at least one protective metal layer 504 is configured to be soldered to or contact an external element.

In the surface finish structure of the multi-layer substrate of the present disclosure, the protective metal layer mainly only covers the upper surface of the pad layer and does not externally expand from two sides of the pad layer. Accordingly, the problem that the pad layer and the protective metal layer cannot be fined due to unexpected expansion in the prior art can be solved. Furthermore, since there is no height difference between the upper surface of the protective metal layer (or the upper surface of the protective metal layer adjacent to the dielectric layer) and the upper surface of the dielectric layer, air bubbles are not generated between the dielectric layer and the protective metal layer when a surface of a chip is connected to the surface finish structure of the multi-layer substrate by flip-chip bonding. Accordingly, package adhesion of the chip is not weakened, and the problem of poor electrical contact between a surface of the multi-layer substrate and the external component can be avoided. This is technical effect in the present disclosure.

Furthermore, in the surface finish structure of the multi-layer substrate of the present disclosure, there is no height difference between the upper surface of the protective metal layer (or the upper surface of the protective metal layer adjacent to the dielectric layer) and the upper surface of the dielectric layer. When the surface finish structure of the multi-layer substrate is connected to the metal exposed surface of the chip by flip-chip bonding, the air bubbles are not generated between the dielectric layer and the protective metal layer even if the surface finish structure of the multi-layer substrate is completely bonded to the exposed metal surface of the chip without gaps. This is crucial technical effect in high-end semiconductor packaging. When air bubbles are generated after the surface finish structure of the multi-layer substrate is completely bonded to the exposed metal surface of the chip, the air bubbles expand with heat emitted by the chip during operation. At least one electrical connection point of the chip and at least one pad of the multi-layer substrate which are bonded by flip-chip bonding are disconnected from a contacting state. That is, the chip and the multi-layer substrate are changed from a short circuit to an open circuit.

While the preferred embodiments of the present disclosure have been illustrated and described in detail, various modifications and alterations can be made by persons skilled in this art. The embodiment of the present disclosure is therefore described in an illustrative but not restrictive sense. It is intended that the present disclosure should not be limited to the particular forms as illustrated, and that all modifications and alterations which maintain the spirit and realm of the present disclosure are within the scope as defined in the appended claims.

What is claimed is:

1. A surface finish structure of a multi-layer substrate, comprising:
a dielectric layer;
at least one pad layer formed in the dielectric layer; and
at least one protective metal layer formed on the at least one pad layer and bonded to the at least one pad layer, wherein the at least one protective metal layer only covers an upper surface of the at least one pad layer, the at least one protective metal layer is configured to be soldered to or contact an external element, and there is no height difference between an upper surface of the at least one protective metal layer and an upper surface of the dielectric layer.

2. The surface finish structure of the multi-layer substrate according to claim 1, wherein a material of the dielectric layer is polyimide.

3. The surface finish structure of the multi-layer substrate according to claim 1, wherein a material of the at least one pad layer is copper.

4. The surface finish structure of the multi-layer substrate according to claim 1, wherein a material of the at least one protective metal layer is selected from the group consisting of chromium, nickel, palladium, and gold.

5. A surface finish structure of a multi-layer substrate, comprising:
a dielectric layer;
at least one pad layer, wherein a part of the at least one pad layer is formed in the dielectric layer; and
at least one protective metal layer formed on the at least one pad layer and bonded to the at least one pad layer, wherein the at least one protective metal layer only covers an upper surface of the at least one pad layer, the at least one protective metal layer is configured to be soldered to or contact an external element, and there is no height difference between an upper surface of the at least one protective metal layer adjacent to the dielectric layer and an upper surface of the dielectric layer.

6. The surface finish structure of the multi-layer substrate according to claim 5, wherein a material of the dielectric layer is polyimide.

7. The surface finish structure of the multi-layer substrate according to claim 5, wherein a material of the at least one pad layer is copper.

8. The surface finish structure of the multi-layer substrate according to claim 5, wherein a material of the at least one protective metal layer is selected from the group consisting of chromium, nickel, palladium, and gold.

9. The surface finish structure of the multi-layer substrate according to claim 5, wherein an upper surface of a remaining part of the at least one protective metal layer excluding the upper surface of the at least one protective metal layer adjacent to the dielectric layer is a protrusion shape or a recessed shape to be completely connected to the external element by flip-chip bonding.

10. The surface finish structure of the multi-layer substrate according to claim 9, wherein a material of the dielectric layer is polyimide.

11. The surface finish structure of the multi-layer substrate according to claim 9, wherein a material of the at least one pad layer is copper.

12. The surface finish structure of the multi-layer substrate according to claim 9, wherein a material of the at least one protective metal layer is selected from the group consisting of chromium, nickel, palladium, and gold.
